(19) United States
(12) Patent Application Publication
(10) Pub. No.: US 2025/0105803 A1
(43) Pub. Date: Mar. 27, 2025

(54) MULTI-CHANNEL AMPLIFIER WITH SOFT COMMON RETURN POINT

(71) Applicant: Cirrus Logic International Semiconductor Ltd., Edinburgh (GB)

(72) Inventor: John L. MELANSON, Austin, TX (US)

(73) Assignee: Cirrus Logic International Semiconductor Ltd., Edinburgh (GB)

(21) Appl. No.: 18/647,100

(22) Filed: Apr. 26, 2024

Related U.S. Application Data
(60) Provisional application No. 63/584,671, filed on Sep. 22, 2023.

(51) Int. Cl. H03F 3/21

(52) U.S. Cl. CPC H03F 3/211; H03F 2200/03

(57) ABSTRACT

A system may include a signal processor that receives a first input signal from a first channel switching amplifier of a multi-channel amplifier and a second input signal from a second channel switching amplifier of the multi-channel amplifier, wherein the first channel switching amplifier and the second channel switching amplifier share a capacitor that has a first terminal coupled to a common terminal that is coupled to a first negative polarity of the first channel switching amplifier and a second positive polarity of the second channel switching amplifier and a second terminal that is coupled to a ground. The signal processor may be configured to receive the first input signal and the second input signal and modify the first input signal into the first channel switching amplifier and the second input signal into the second channel switching amplifier to regulate a common mode signal at the common terminal.

### RELATED APPLICATION

The present disclosure claims priority to U.S. Provisional Application Ser. No. 63/584,671 filed Sep. 22, 2023, which is incorporated by reference herein in its entirety.

### FIELD OF DISCLOSURE

The present disclosure relates in general to circuits for electronic devices, including without limitation audio devices, piezoelectric devices, haptic-feedback devices, wireless telephones, media players, and/or mobile devices, and more specifically, to circuits including resistors for sensing current in an electronic device.

### BACKGROUND

Many electronic devices, including without limitation audio devices, piezoelectric devices, haptic-feedback devices, wireless telephones, media players, and/or mobile devices, may include a multi-channel amplifier. Such multi-channel amplifier may be used for any suitable purposes, including driving multiple loudspeakers, piezoelectric actuators, haptic actuators, or any other suitable actuators.

Multi-channel amplifiers in which outputs of the multiple channels share a decoupling capacitor are known. For example, U.S. Pat. No. 7,822,214 (the “'214 Patent”) provides an example of such capacitor sharing and discloses an audio power output system with a shared output blocking capacitor. The '214 patent depicts a pair of transducers series-connected in opposite polarity, and a common direct-current (DC) blocking capacitor provides the return path to a power supply rail in common with a pair of audio power output stages having output terminals each connected to one of the other terminals of a corresponding transducer. In such a multi-channel amplifier, the current through the capacitor being shared by the two amplifiers is zero when the two amplifiers are being driven by the same signal. However, when the amplifiers are driven by two different signals, the current through the capacitor is the difference between the two different signals. The capacitor integrates the current, and the voltage on the capacitor may represent a low-pass filtered version of the difference between the two amplifier signals, which may modify the differential frequency response and thus may spatially modify acoustic location of the signals.

Furthermore, systems and methods are known for modifying an amplifier depending on its dynamic range. For example, a presentation entitled “How ST automotive amplifiers can improve audio quality and efficiency for in-car applications” by Matteo Bellitra and Rosario Insolera provides such examples. A dynamic range problem may exist when an amplifier is being modified at high frequency and may lead to presence of common mode noise. Thus, the need and desire to improve signal integrity without clipping in an amplifier continues to exist.

### SUMMARY

In accordance with the teachings of the present disclosure, one or more disadvantages and problems associated with existing approaches to minimizing noise and distortion in a multi-channel amplifier may be reduced or eliminated.

In accordance with embodiments of the present disclosure, a system may include a plurality of channel switching amplifiers comprising a first channel switching amplifier for driving a first transducer with a first voltage having a first positive polarity and a first negative polarity and a second channel switching amplifier for driving a second transducer with a second voltage having a second positive polarity and a second negative polarity. The system may also include a capacitor having a first terminal and a second terminal wherein the first terminal is coupled to a common terminal coupled to the first negative polarity and the second positive polarity and wherein the second terminal coupled to a ground, a feedback path coupled to the common terminal wherein the feedback path is utilized to isolate the first channel switching amplifier and the second channel switching amplifier from each other and ensure a flat frequency response of the system, and a signal processor that processes a first input signal from the first channel switching amplifier, a second input signal from the second channel switching amplifier, and a feedback signal from the feedback path to control a voltage range of the common terminal.

In accordance with these and other embodiments of the present disclosure, a system may include a signal processor that receives a first input signal from a first channel switching amplifier of a multi-channel amplifier and a second input signal from a second channel switching amplifier of the multi-channel amplifier, wherein the first channel switching amplifier and the second channel switching amplifier share a capacitor that has a first terminal coupled to a common terminal that is coupled to a first negative polarity of the first channel switching amplifier and a second positive polarity of the second channel switching amplifier and a second terminal that is coupled to a ground. The signal processor may be configured to receive the first input signal and the second input signal and modify the first input signal into the first channel switching amplifier and the second input signal into the second channel switching amplifier to regulate a common mode signal at the common terminal.

In accordance with these and other embodiments of the present disclosure, a method may be provided for a system having a plurality of channel switching amplifiers including a first channel switching amplifier for driving a first transducer with a first voltage having a first positive polarity and a first negative polarity and a second channel switching amplifier for driving a second transducer with a second voltage having a second positive polarity and a second negative polarity and the system further having a capacitor having a first terminal and a second terminal wherein the first terminal is coupled to a common terminal coupled to the first negative polarity and the second positive polarity and wherein the second terminal coupled to a ground. The method may include isolating, with a feedback path coupled to the common terminal, the first channel switching amplifier and the second channel switching amplifier from each other and to ensure a flat frequency response of the system. The method may also include controlling a voltage range of the common terminal by processing a first input signal from the first channel switching amplifier, a second input signal from the second channel switching amplifier, and a feedback signal.

In accordance with these and other embodiments of the present disclosure, a method may include receiving a first input signal from a first channel switching amplifier of a multi-channel amplifier and a second input signal from a second channel switching amplifier of the multi-channel amplifier, wherein the first channel switching amplifier and the second channel switching amplifier share a capacitor that has a first terminal coupled to a common terminal that is coupled to a first negative polarity of the first channel switching amplifier and a second positive polarity of the second channel switching amplifier and a second terminal that is coupled to a ground. The method may also include modifying the first input signal into the first channel switching amplifier and the second input signal into the second channel switching amplifier to regulate a common mode signal at the common terminal.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates selected components of an example multi-channel amplifier, in accordance with embodiments of the present disclosure;

FIG. 2 illustrates selected components of an example inductive-capacitive filter, in accordance with embodiments of the present disclosure;

FIG. 3 shows an example plot of common mode voltages of the multi-channel amplifier of FIG. 1, in accordance with embodiments of the present disclosure;

FIG. 4 illustrates selected components of an example signal processor that may be used as a signal processor in the multi-channel amplifier of FIG. 1, in accordance with embodiments of the present disclosure;

FIGS. 5A and 5B each illustrate plots of example differential filter responses for a differential filter, in accordance with embodiments of the present disclosure;

FIG. 6 illustrates selected components of another example signal processor that may be used as a signal processor in the multi-channel amplifier of FIG. 1, in accordance with embodiments of the present disclosure;

FIGS. 7A and 7B each illustrate plots of example differential filter responses for a differential filter, in accordance with embodiments of the present disclosure;

FIG. 8 illustrates selected components of another example multi-channel amplifier, in accordance with embodiments of the present disclosure;

FIG. 9 illustrates selected components of yet another example multi-channel amplifier, in accordance with embodiments of the present disclosure;

FIG. 10 illustrates a plot of example gain versus frequency for the differential filter shown in FIG. 9, in accordance with embodiments of the present disclosure;

FIG. 11 illustrates selected components of an example multi-channel amplifier having four channels, in accordance with embodiments of the present disclosure;

FIG. 12 illustrates selected components of yet another example multi-channel amplifier, in accordance with embodiments of the present disclosure; and

FIG. 13 illustrates selected components of an example return amplifier, in accordance with embodiments of the present disclosure.

### DETAILED DESCRIPTION

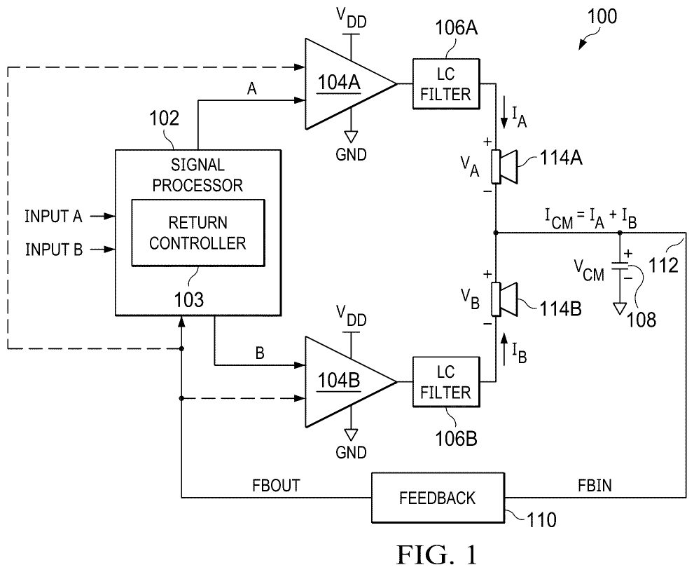

FIG. 1 illustrates selected components of an example multi-channel amplifier 100, in accordance with embodiments of the present disclosure. As shown in FIG. 1, multi-channel amplifier 100 may include a first channel switching amplifier 104A (e.g., a Class-D amplifier), a second channel switching amplifier 104B (e.g., a Class-D amplifier), a capacitor 108, and a feedback path 110 coupled to a terminal of capacitor 108. First channel switching amplifier 104A may drive a first transducer 114A with a first current I_{A} and a first voltage V_{A} having a first positive polarity and a first negative polarity. Similarly, second channel switching amplifier 104B may drive a second transducer 114B with a second current I_{B} and a second voltage V_{B} having a second positive polarity and a second negative polarity.

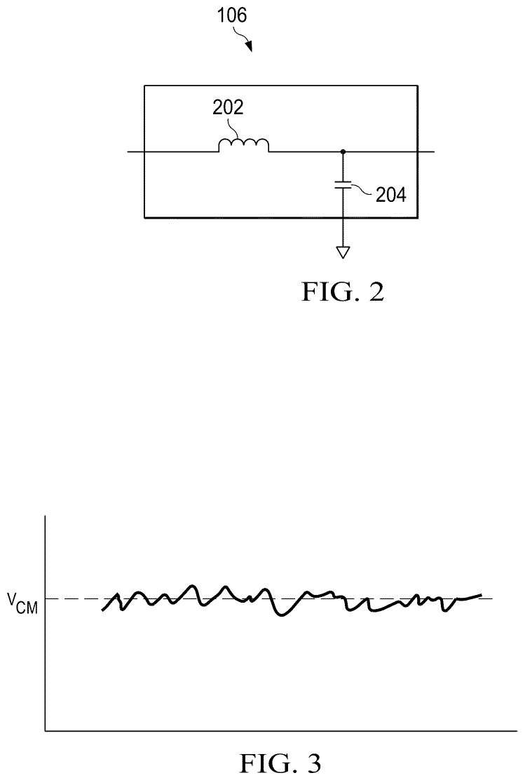

The first channel of multi-channel amplifier 100 may include an inductor-capacitor filter (LC) 106A coupled between the output of first channel switching amplifier 104A and first transducer 114A, and similarly, the second channel of multi-channel amplifier 100 may include an LC filter 106B coupled between the output of second channel switching amplifier 104B and second transducer 114B. FIG. 2 illustrates selected components of an example LC filter 106, in accordance with embodiments of the present disclosure, which may be used to implement each of LC filters 106A and 106B. As depicted in FIG. 2, LC filter 106 may include inductor 202 and capacitor 204 coupled together in the manner shown. A first terminal of inductor 202 may serve as an input node of LC filter 106, while a second terminal of inductor 202 may be coupled to a first terminal of capacitor 204 and serve as an output of LC filter 106. A second terminal of capacitor 204 may be coupled to ground.

Turning again to FIG. 1, capacitor 108 may have a first terminal coupled to a common terminal 112 which itself is coupled to the first negative polarity and the second positive polarity, and a second terminal coupled to ground. An input of feedback path 110 may also be coupled to common terminal 112. A current I_{CM} at common terminal 112 may be the difference between first current I_{A} and second current I_{B} (e.g., I_{CM}=I_{A}−I_{B}). As described in greater detail below, feedback path 110 may function to isolate first channel switching amplifier 104A and second channel switching amplifier 104B and/or to ensure a flat frequency response.

As further shown in FIG. 1, multi-channel amplifier 100 may also include a signal processor 102. The signal processor 102 may include a return controller 103, although in some embodiments, return controller 103 may be a separate block external to signal processor 102. Signal processor 102 may process a first input signal (INPUT A) for first channel switching amplifier 104A, a second input signal (INPUT B) for second channel switching amplifier 104B, and a feedback output signal FBOUT generated by feedback path 110 in order to control a voltage range of common terminal 112, for example by controlling common mode voltage V_{CM} across capacitor 108.

Feedback path 110 may receive feedback input signal FBIN at its input, which may comprise a signal from the first terminal of capacitor 108 (i.e., common terminal 112). Thus, feedback path 110 may receive and process feedback input signal FBIN to generate feedback path output signal FBOUT.

Return controller 103 may receive INPUT A and INPUT B and feedback path output signal FBOUT and based thereon, generate returned-controlled signals A and B as inputs into switching amplifiers 104A and 104B.

As mentioned, feedback (i.e., feedback input signal FBIN) may be provided from common terminal 112. In operation, signal processor 102 may generate signal A based on signal INPUT A, either by passing INPUT A as signal A or modifying INPUT A to generate signal A based on conditioning/programmed operation(s) and/or feedback path output signal FBOUT. Similarly, signal processor 102 may generate signal B based on signal INPUT B, either by passing INPUT B as signal B or modifying INPUT B to generate signal B based on conditioning/programmed operation(s) and/or feedback path output signal FBOUT. For example, signals A and B may be modified by signal processor 102 in order to return the difference between the two transducer driving currents back to zero (i.e., I_{CM}=I_{A}−I_{B}=0) measured over bandwidth or time scale. By analyzing common terminal 112 via feedback path 110, signal processor 102 may modify INPUT A and INPUT B for not only producing audio or other transducer output content, but to also regulate common mode voltage V_{CM} across capacitor 108. For example, in some embodiments, it may be desirable to provide a fast-changing voltage close enough to the midpoint of common mode voltage V_{CM} so that clipping is avoided. Such a midpoint may be between supply voltage V_{DD} and ground (e.g., V_{DD}/2).

A signal (i.e., signals A and B based on respective INPUT A and INPUT B) driven into multi-channel amplifier 100 may be a differential power of channel switching amplifiers 104A and 104B that drive respective transducers 114A and 114B. Signal processor 102 may compress or expand INPUT A and/or INPUT B in order to regulate common mode voltage V_{CM}. For example, signal processor 102 may modify the signal being driven into multi-channel amplifier 100, wherein such modifying may include modification by compression to a playback signal into one or more channel switching amplifiers (104A and 104B) or by expansion to a playback signal into one or more channel switching amplifiers 104A and 104B, or modification one or more filters on a playback signal into one or more channel switching amplifiers 104A and 104B. Signal processor 102 may modify the one or more filters by moving filter corner frequencies, altering attenuation, altering gain, and/or altering the quality factor of the one or more filters. Furthermore, signal processor 102 may modify the one or more filters being driven into multi-channel amplifier 100 by adding signals into a playback signal into the one or more channel switching amplifiers 104A and 104B. For example, for a channel switching amplifier 104A/104B that has low frequency signals, signal processor 102 may add one or more high frequency signals for regulating the common mode signal. Thus, signal processor 102 may modify the signal being driven into the multi-channel amplifier 100 to regulate common mode voltage V_{CM} or the differential power of channel switching amplifiers 104A and 104B. Further, signal processor 102 may in some instances increase a gain of the differential signal, which may increase an apparent stereo width of the signal. By monitoring common mode voltage V_{CM}, signal processor 102 may determine times in which such widening of the stereo width may occur without adding distortion.

Embodiments of the present disclosure may include, but are not limited to, signal processor 102 using feedback from capacitor 108, centering of an offset without using feedback, using feedback without centering an offset, and/or inferring common mode voltage V_{CM} by analyzing a duty cycle of one or both of channel switching amplifiers 104A and 104B.

Signal processor 102 may modify INPUT A and INPUT B to generate signals A and B based on feedback output signal FBOUT. Thus, signal processor 102 may be able to control a voltage range of common terminal 112 (i.e., common mode voltage V_{CM}), or more specifically to regulate a common mode signal at common terminal 112, based on signals A and B whether or not they are modified, and if they are modified, such modifications to INPUT A and INPUT B may also be based on the feedback signal, such as feedback output signal FBOUT. The signal driven into the multi-channel amplifier 100 may be a differential power of the two or more channel switching amplifiers 104A and 104B. Signal processor 102 may modify such driven signal to regulate the common mode signal or the differential power of the two or more channel switching amplifiers 104A and 104B.

Further, signal processor 102 may modify the voltage range of common mode voltage V_{CM} and/or the current range of current I_{CM} may be modified to improve an efficiency of the amplifier (i.e., multi-channel amplifier 100) because common voltage V_{CM} may affect amplifier efficiency. For example, amplifier efficiency tends to improve when common mode voltage V_{CM} is modified away from the midpoint (i.e., moved away from V_{DD}/2 in FIG. 1). FIG. 3 shows an example plot of common mode voltages V_{CM}, in accordance with embodiments of the present disclosure.

Feedback output signal FBOUT from feedback path 110 may be utilized by signal processor 102 to ensure isolation of transducers 106A and 106B. Feedback path 110, feedback input signal FBIN, and feedback output signal FBOUT may be implemented in various ways. For example, feedback input signal FBIN and/or feedback output signal FBOUT may be analog signals, or may be digitized signals in which calculations are performed in the digital domain, or a combination thereof. Feedback input signal FBIN, and feedback output signal FBOUT may enforce isolation of the channels and flat frequency response of multi-channel amplifier 100. Feedback input signal FBIN, and feedback output signal FBOUT may also compensate for any non-linearity in capacitor 108 and/or may allow for lower-cost components to be used in the implementation of multi-channel amplifier 100.

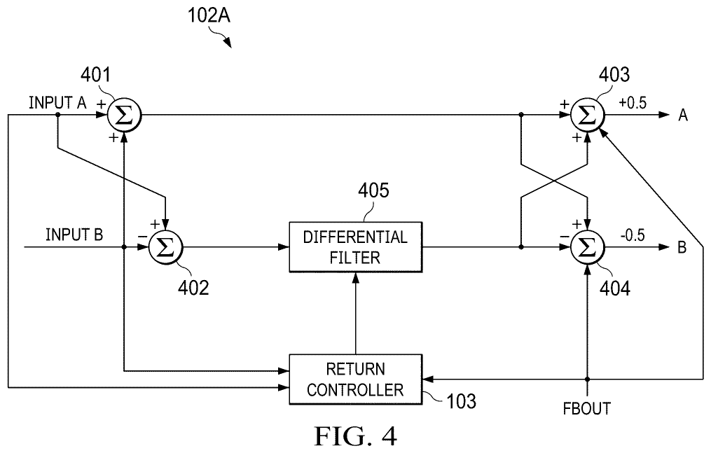

For example, FIG. 4 illustrates selected components of an example signal processor 102A that may be used as signal processor 102 in FIG. 1. Signal processor 102A may include summers 401 and 402, and each summer 401 and 402 may receive as inputs both of INPUT A and INPUT B as shown in FIG. 4. Summer 401 may receive INPUT A as a positive input and INPUT B as another positive input and sum together such inputs. Summer 401 may provide its output directly to both summer 403 and summer 404. Summer 402 may receive input A as a positive input and input B as a negative input and may also sum such inputs. Summer 402 may provide its output to a differential filter 405. Return controller 103 may also receive INPUT A, INPUT B, and feedback output signal FBOUT as inputs and, in turn, generate a return control signal output to differential filter 405. Differential filter 405 may also receive the output of summer 402 as another one of its inputs. Differential filter 405 may process and perform filtering operations on these input signals to generate a differential filtered output signal to both summer 403 and summer 404. Summer 403 may sum INPUT A (positive input), the differential filtered output signal (positive input), and feedback output signal FBOUT to provide a summed value that represents signal A with a positive 0.5 gain. Summer 404 may sum INPUT B (positive input), the differential filtered output signal (negative input), and feedback output signal FBOUT to provide a summed value that represents signal B with a negative 0.5 gain.

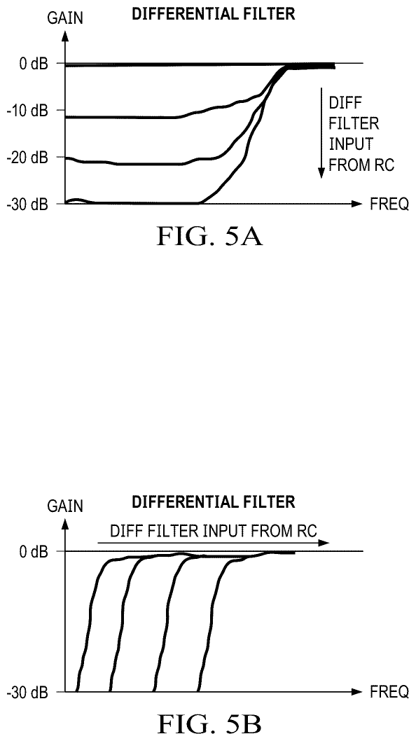

FIGS. 5A and 5B each illustrate plots of example differential filter responses for differential filter 405, in accordance with embodiments of the present disclosure. FIG. 5A illustrates an example plot of gain versus frequency for a response of differential filter 405 implemented as a shelving filter. FIG. 5A further illustrates a gain of differential filter 405 from −30 dB to 0 dB plotted over an increasing frequency range. The arrow in FIG. 5A depicts a direction of increase return control signal communicated from return controller 103 to differential filter 405. FIG. 5B illustrates an example plot of gain versus frequency for a response of differential filter 405 implemented as a Butterworth filter. FIG. 5B further illustrates a gain of differential filter 405 from −30 dB to 0 dB plotted over an increasing frequency range. The arrow in FIG. 5B depicts a direction of increase return control signal communicated from return controller 103 to differential filter 405. FIGS. 5A and 5B depict two example embodiments of how differential filter 405 may be implemented according to the present disclosure. However, the present disclosure may not be limited to just the two example embodiments and implementations for differential filter 405, and there are many other various ways that the differential filter 405 may be implemented or provided. For example, differential filter 405 may be a variable low pass filter, high pass filter, or other type of filter.

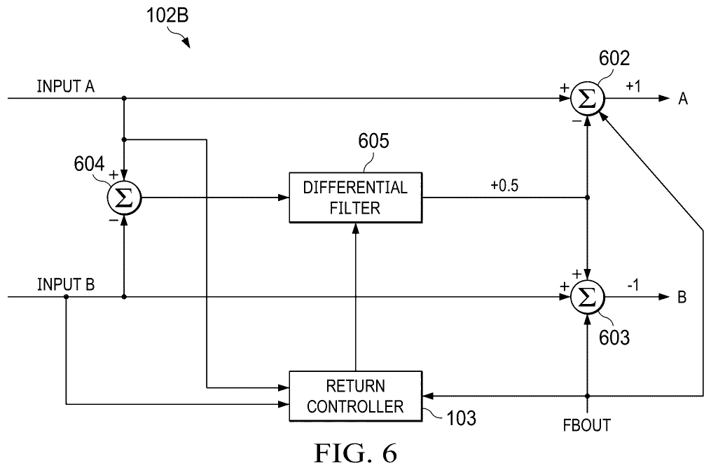

FIG. 6 illustrates selected components of an example signal processor 102B that may be used as signal processor 102 in FIG. 1. Signal processor 102B may include summer 604, which may receive INPUT A as a positive input and INPUT B as a negative input. Summer 604 may sum together these inputs and provide its output to a differential filter 605. Return controller 103 may also receive INPUT A, INPUT B, and feedback path output signal FBOUT as inputs, and, in turn, generate a return control signal output to differential filter 605. Differential filter 605 may perform filtering operations based on the summed output from summer 604 and the return control signal from return controller 103 to generate a differential-filtered output with a 0.5 gain. Summer 602 may sum INPUT A (positive input), the differential-filtered output (negative 0.5 gain), and feedback signal FBOUT to generate a summed value that may represent signal A having a positive 1 gain. Summer 603 may sum INPUT B (positive input), the differential-filtered output (positive 0.5 gain), and feedback signal FBOUT to provide a summed value that may represent signal B with a −1 gain.

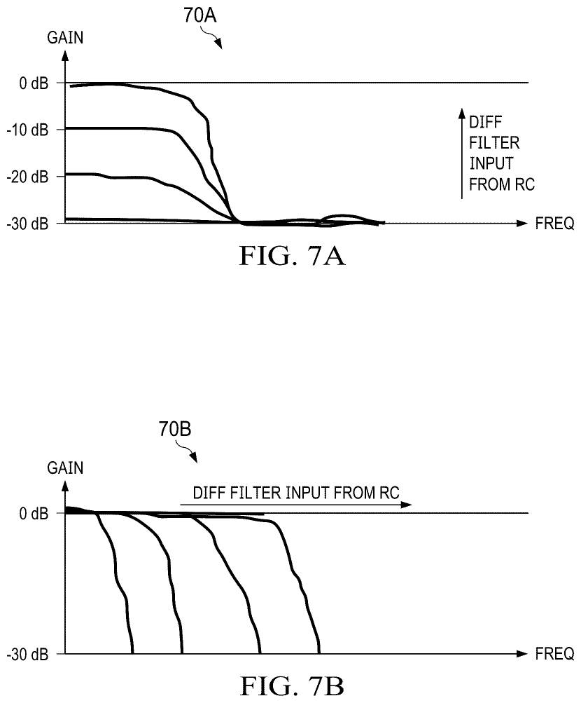

FIGS. 7A and 7B each illustrate plots of example differential filter responses for differential filter 605, in accordance with embodiments of the present disclosure. FIG. 7A illustrates an example plot of gain versus frequency for a response of differential filter 605 implemented as a shelving filter. FIG. 7A further illustrates a gain of differential filter 605 from −30 dB to 0 dB plotted over an increasing frequency range. The arrow in FIG. 7A depicts a direction of increase return control signal communicated from return controller 103 to differential filter 605. In FIG. 7A, the shelving filter may be implemented as a variable low-pass filter and may allow signals at low frequencies to be passed through and processed. The transitional frequency at and below which low frequency signals are considered and passed may depend on the characteristics of transducers 106A and 106B and multi-channel amplifier 100. The transitional frequency is 100 Hz, but also may be in the range of 10 Hz to 1000 Hz.

FIG. 7B illustrates an example plot of gain versus frequency for a response of differential filter 605 implemented as a Butterworth filter. FIG. 7B further illustrates a gain of differential filter 605 from −30 dB to 0 dB plotted over an increasing frequency range. The arrow in FIG. 7B depicts a direction of increased return control signal communicated from return controller 103 to differential filter 605. In FIG. 7B, the Butterworth filter may be implemented as a high pass filter and may allow the signals at high frequencies to be passed through and processed while removing and filtering out the signals at low frequencies. The transitional frequency at and above which low frequency signals are considered and passed may depend on the characteristics of transducers 106A and 106B and multi-channel amplifier 100. The transitional frequency is 100 Hz, but also may be in the range of 10 Hz to 1000 Hz.

FIGS. 7A and 7B depict two example embodiments of how differential filter 605 may be implemented according to the present disclosure. However, the present disclosure may not be limited to just the two example embodiments and implementations for differential filter 605, and there are many other various ways that the differential filter 605 may be implemented or provided. For example, differential filter 605 may be a variable low pass filter, high pass filter, or other type of filter.

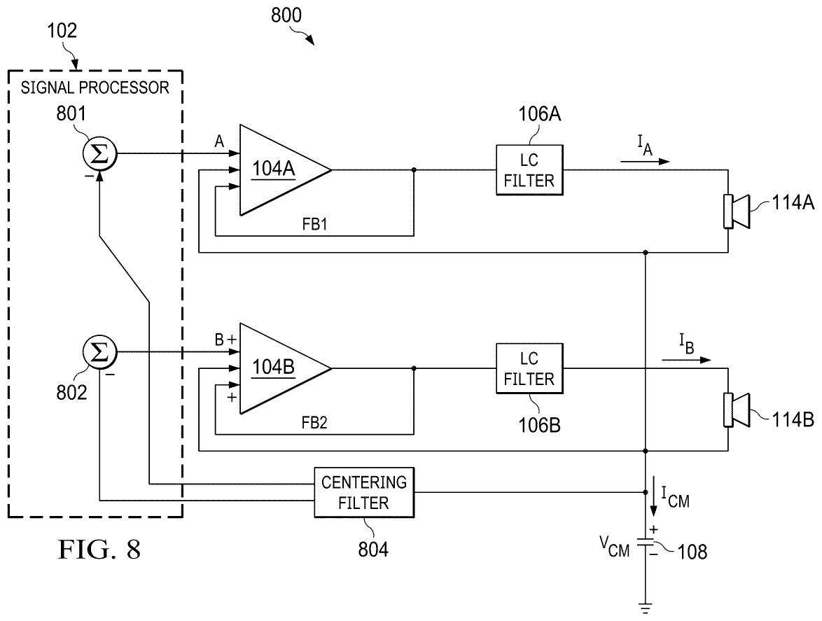

FIG. 8 illustrates selected components of an example multi-channel amplifier 800, in accordance with embodiments of the present disclosure. Multi-channel amplifier 800 may be similar in many respects to multi-channel amplifier 100 of FIG. 1, and thus only the main differences between multi-channel amplifier 100 and multi-channel amplifier 800 may be pictured in FIG. 8 and described below. One difference between multi-channel amplifier 100 and multi-channel amplifier 800 is that in multi-channel amplifier 800, feedback output signal FBOUT may be directly fed into first channel switching amplifier 104A and second channel switching amplifier 104B, which is represented in FIG. 1 by dashed lines. As also shown in FIG. 8, multi-channel amplifier 800 may include a signal processor 102 with output summers 801 and 802 (which may be similar or identical to summers 403 and 404 respectively, or similar or identical to summers 602 and 603 respectively). The output of summer 801 may be fed to an input of first channel switching amplifier 104A and the output of summer 802 may be fed to an input of second channel switching amplifier 104B. The outputs of channel switching amplifiers 104A and 104B may be driven into respective LC filters 106A and 106B and respective transducers 114A and 114B as shown in FIG. 8. The signal across transducer 114A may be provided as a feedback signal FB1 (i.e., part of feedback path output signal FBOUT) back into first channel switching amplifier 104A, and the signal across transducer 114B may be provided as a feedback signal FB2 (i.e., part of feedback path output signal FBOUT) back into second channel switching amplifier 104B.

In the presence of any offset in multi-channel amplifier 800, or a DC term on any inputs, common mode voltage V_{CM} may stray from the midpoint (e.g., V_{DD}/2) potentially causing saturation of either or both of first channel switching amplifier 104A and second channel switching amplifier 104B. A centering filter 804 may remove such offset. In operation, centering filter 804 may return low frequency (e.g., sub audio band) information to the input of each of first channel switching amplifier 104A and second channel switching amplifier 104B. Centering filter 804 may be a low pass filter that allows the low frequency information to pass through. The signals may be processed as either analog signals or digital signals.

When there is a large, low frequency out-of-phase signal on the inputs (e.g., INPUT A and INPUT B) to multi-channel amplifier 100 or multi-channel amplifier 800, capacitor 108 may no longer be able to keep the return or feedback signal near the center, potentially causing clipping of either or both of first channel switching amplifier 104A and second channel switching amplifier 104B, and resulting in distortion. Thus, centering filter 804 may reduce the differential current signal I_{CM} at low frequencies when needed. In other words, centering filter 804 may be a high-pass filter that filters out the differential signal at low frequencies, and thus may attenuate differential current signal I_{CM} as needed to maintain desired headroom. Examples of centering filter 804 include a shelving filter, with variable shelf level, and a filter for moving the corner frequency. Other types of filters may be used for centering filter 804, although a shelving filter may be well-suited for the centering filter 804 because of the ease of low-distortion embodiments. The removed differential current signal I_{CM} may be at low frequencies, and the low-frequency differential current signal I_{CM} may be replaced with a pseudo-bass signal created by a non-linear process and by appropriate level controls. Such signal replacement may give an acoustic effect similar to the out-of-phase bass signal.

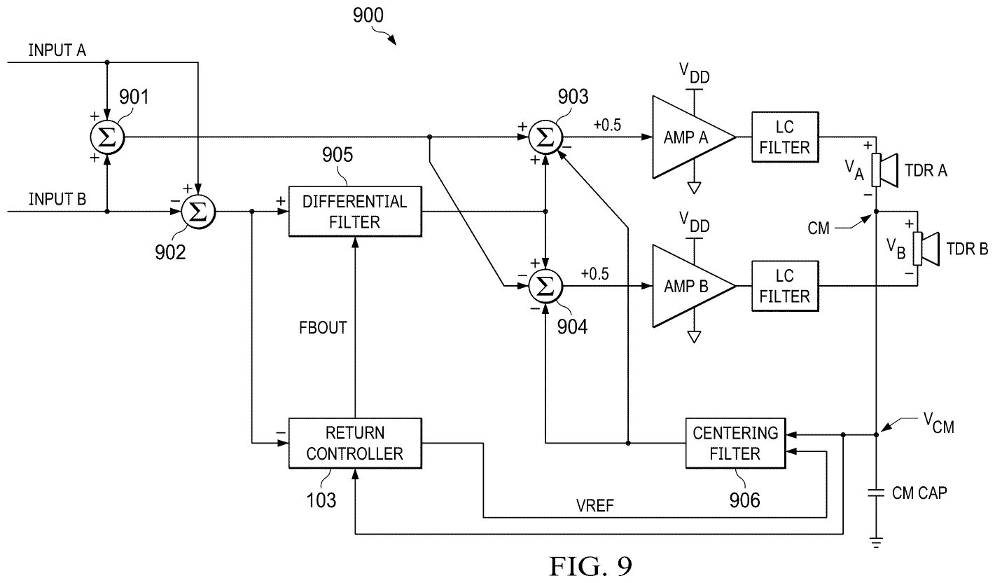

FIG. 9 illustrates selected components of an example multi-channel amplifier 900, in accordance with embodiments of the present disclosure. Multi-channel amplifier 900 may be similar in many respects to multi-channel amplifier 100 of FIG. 1 and multi-channel amplifier 800 of FIG. 8, and thus only the main differences of multi-channel amplifier 900 from multi-channel amplifier 100 and multi-channel amplifier 800 may be pictured in FIG. 9 and described below. In particular, a main difference of multi-channel amplifier 900 is that feedback path output signal FBOUT may instead be generated by return controller 103. Such feedback is depicted in FIG. 1 as the non-dashed input line FBOUT into signal processor 102. Return controller 103 of multi-channel amplifier 900 may be part of feedback path 110 of FIG. 1. In multi-channel amplifier 900, summer 901 may receive INPUT A as a positive input and INPUT B as a positive input, and summer 902 may receive INPUT A as a positive input and INPUT B as a negative input. Summer 901 may provide its summed output as a positive input into summer 903 and as a negative input into summer 904. Summer 902 may provide its summed output as a positive input into a differential filter 905 and as a negative input into return controller 103. Differential filter 905 may perform filter operations and provide its filtered output as positive inputs into summer 903 and summer 904. Common mode voltage V_{CM} and a reference voltage VREF from return control block 103 may be fed as inputs into a centering filter 906. Centering filter 906 may be able to adjust the centering of common mode voltage V_{CM}. The center filtered output from centering filter 906 may be provided as negative inputs into summers 903 and 904. Centering filter 906 may be a low pass filter that allows through low-frequency signals and filters out high-frequency signals.

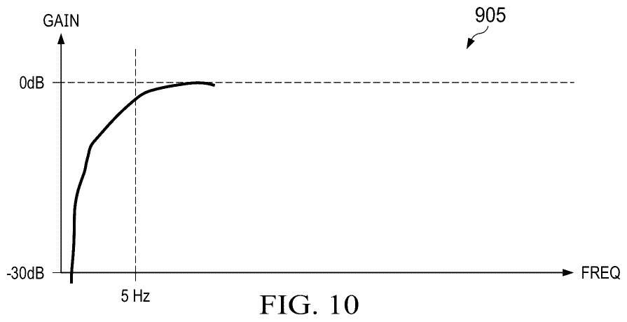

FIG. 10 illustrates a plot of example gain versus frequency for differential filter 905, in accordance with embodiments of the present disclosure.

While FIGS. 1, 4, 6, 8, and 9 depict multi-channel amplifiers with two channel switching amplifiers (e.g., channel switching amplifiers 104A and 104B), systems and methods in accordance with the present disclosure can use any number of two or more channels. In fact, the use of more than two channels may be more advantageous.

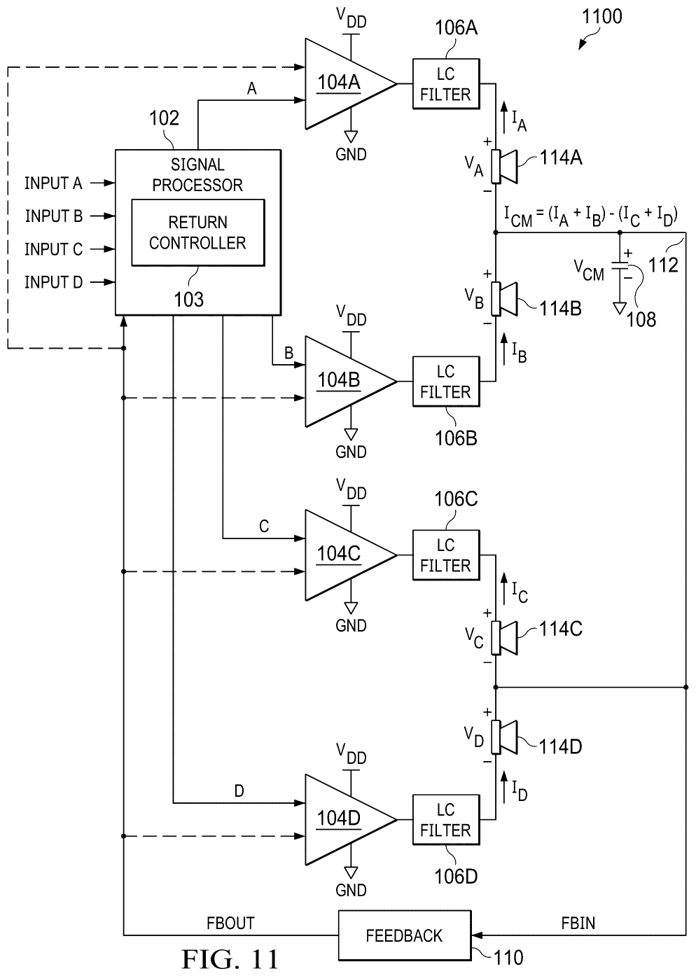

As an example, FIG. 11 illustrates selected components of an example multi-channel amplifier 1100 having four channels, in accordance with embodiments of the present disclosure. Multi-channel amplifier 1100 may be similar in many respects to multi-channel amplifier 100 of FIG. 1, and thus only the main differences between multi-channel amplifier 100 and multi-channel amplifier 1100 may be pictured in FIG. 11 and described below. As shown in FIG. 11, multi-channel amplifier 1100 may include four channel switching amplifiers 104A, 104B, 104C, and 104D. Channel switching amplifiers 104A and 104B may be coupled in multi-channel amplifier 1100 in the same manner as multi-channel amplifier 100 of FIG. 1. In other words, the node between the first negative polarity of transducer 114A and the second positive polarity of transducer 114B may be coupled to common terminal 112. In addition, channel switching amplifier 104C may receive a signal C from signal processor 102/return controller 103 based on an INPUT C, and channel switching amplifier 104D may receive a signal D from signal processor 102/return controller 103 based on an INPUT D. The output of channel switching amplifier 104C may drive output current I_{C} to transducer 114C, and the output of channel switching amplifier 104D may drive output current I_{D} to transducer 114D. The node between the negative polarity of transducer 114C and the positive polarity of transducer 114D may be coupled to common terminal 112. For multi-channel switching amplifier 1100, the third or more channel amplifiers (i.e., channel switching amplifiers 104C and 104D) that receive respective signals C and D based on INPUT C and INPUT D may help isolate the various channel switching amplifiers from each other and ensure a flat frequency response. The signals C and D being driven into multi-channel amplifier 1100 may also be another differential power of the channel switching amplifiers 104C and 104D. A loop may be closed around channel switching amplifiers 104C and 104D with feedback path 110 and a feed forward path that calculates another differential power of channel switching amplifiers 104C and 104D. A differential filter (not shown in FIG. 11) may receive a return control signal from the signal processor 102/return controller 103 and may operate to help calculate the differential power of channel switching amplifiers 104C and 104D. Other than these differences, multi-channel amplifier 1100 may operate in a similar manner as multi-channel amplifier 100.

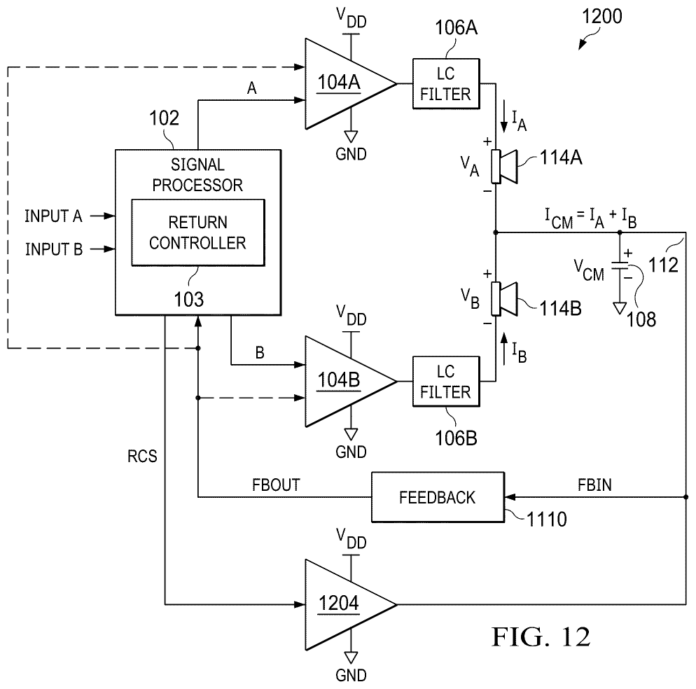

FIG. 12 illustrates selected components of an example multi-channel amplifier 1200, in accordance with embodiments of the present disclosure. Multi-channel amplifier 1200 may be similar in many respects to multi-channel amplifier 100 of FIG. 1, and thus only the main differences between multi-channel amplifier 100 and multi-channel amplifier 1200 may be pictured in FIG. 12 and described below. One main difference is that multi-channel amplifier 1200 may include an additional return amplifier 1204 coupled between return controller 103 and common terminal 112. Return amplifier 1204 may receive as its input a return control signal RCS output from return controller 103 and provide its amplified output to common terminal 112. However, return amplifier 1204 may provide less current drive than channel switching amplifiers 104A and 104B (e.g., return amplifier 1204 current output may be significantly less than current I_{A} and current I_{B}).

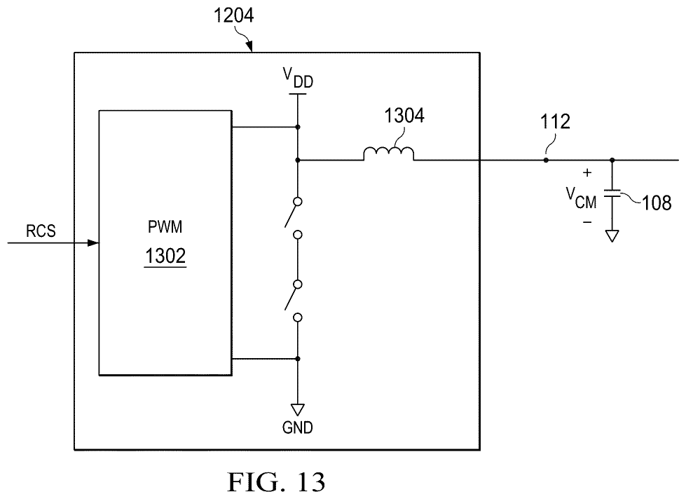

FIG. 13 illustrates selected components of an example return amplifier 1204, in accordance with embodiments of the present disclosure. As shown in FIG. 13, return amplifier 1204 may include a pulse-width-modulator (PWM) 1302. PWM 1302 may receive as its input return control signal RCS output from return controller 103. Outputs of PWM 1302 may be fed into and coupled to supply voltage V_{DD} as shown in FIG. 13. A first terminal of an inductor 1304 may be coupled to supply voltage V_{DD} as shown in FIG. 13. A second terminal of the inductor 1304 may be coupled to common terminal 112 which, in turn, may also be coupled to capacitor 108 as shown in FIG. 13, and may provide the output of return amplifier 1204, wherein return amplifier 1204 may be small.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
a plurality of channel switching amplifiers comprising:
a first channel switching amplifier for driving a first transducer with a first voltage having a first positive polarity and a first negative polarity; and
a second channel switching amplifier for driving a second transducer with a second voltage having a second positive polarity and a second negative polarity;
a capacitor having a first terminal and a second terminal wherein the first terminal is coupled to a common terminal coupled to the first negative polarity and the second positive polarity and wherein the second terminal coupled to a ground;
a feedback path coupled to the common terminal wherein the feedback path is utilized to isolate the first channel switching amplifier and the second channel switching amplifier from each other and ensure a flat frequency response of the system; and
a signal processor that processes a first input signal from the first channel switching amplifier, a second input signal from the second channel switching amplifier, and a feedback signal from the feedback path to control a voltage range of the common terminal.

2. The system of claim 1, wherein the signal processor receives the first input signal, the second input signal, and the feedback signal and wherein the signal processor is configured to modify the first input signal into the first channel switching amplifier and the second input signal into the second channel switching amplifier to regulate a common mode signal at the common terminal.

3. The system of claim 2, wherein the common mode signal is a common mode voltage.

4. The system of claim 1, wherein a signal being driven into the plurality of channel switching amplifiers is a differential power of the first channel switching amplifier and the second channel switching amplifier that drive the first transducer and the second transducer, respectively.

5. The system of claim 4, wherein the signal processor is further configured to modify the signal being driven into the plurality of channel switching amplifiers to regulate a common mode signal or the differential power of the first channel switching amplifier and the second channel switching amplifier.

6. The system of claim 1, wherein the plurality of channel switching amplifiers further comprise one or more additional channel switching amplifiers each having respective input signals that isolate the various channel switching amplifiers from each other and ensure a flat frequency response.

7. The system of claim 6, wherein a signal being driven into the one or more additional channel switching amplifiers is a differential power of the one or more additional channel switching amplifiers that drive the transducers.

8. The system of claim 7, wherein a loop is closed around a third or more channel switching amplifier with the feedback path of a common mode signal and a feed forward path that calculates the differential power of the plurality of channel switching amplifiers.

9. The system of claim 7, further comprising a differential filter that receives a return control signal from the signal processor and that operates to calculate the differential power of the plurality of channel switching amplifiers.

10. The system of claim 7, wherein the signal processor is further configured to modify a signal being driven into the plurality of channel switching amplifiers to regulate a common mode signal or the differential power of the plurality of channel switching amplifiers.

11. The system of claim 10, wherein the signal processor is further configured to modify the signal being driven into the plurality of channel switching amplifiers by compression to a playback signal into the plurality of channel switching amplifiers.

12. The system of claim 10, wherein the signal processor is further configured to modify the signal being driven into the plurality of channel switching amplifiers by expansion to a playback signal into the plurality of channel switching amplifiers.

13. The system of claim 10, wherein the signal processor is further configured to modify the signal being driven into the plurality of channel switching amplifiers by modifying one or more filters on a playback signal into the plurality of channel switching amplifiers.

14. The system of claim 13, wherein the signal processor is further configured to modify the one or more filters by at least one of the following: moving filter corner frequencies, altering attenuation, altering gain, and altering a quality factor of the one or more filters.

15. The system of claim 14, wherein for a channel switching amplifier that has low frequency signals, the signal processor is further configured to add one or more high frequency signals for regulating the common mode signal.

16. The system of claim 10, wherein the signal processor is further configured to modify the signal being driven into the plurality of channel switching amplifiers by adding signals into a playback signal into the plurality of channel switching amplifiers.

17. A system, comprising:
a signal processor that receives a first input signal from a first channel switching amplifier of a multi-channel amplifier and a second input signal from a second channel switching amplifier of the multi-channel amplifier;
wherein the first channel switching amplifier and the second channel switching amplifier share a capacitor that has a first terminal coupled to a common terminal that is coupled to a first negative polarity of the first channel switching amplifier and a second positive polarity of the second channel switching amplifier and a second terminal that is coupled to a ground;
wherein the signal processor is configured to:
receive the first input signal and the second input signal; and
modify the first input signal into the first channel switching amplifier and the second input signal into the second channel switching amplifier to regulate a common mode signal at the common terminal.

18. The system of claim 17, wherein the common voltage signal is a voltage in a voltage range or a current in a current range for the common terminal and is modified to improve an efficiency of the multi-channel amplifier.

19. A method, in a system having a plurality of channel switching amplifiers including a first channel switching amplifier for driving a first transducer with a first voltage having a first positive polarity and a first negative polarity and a second channel switching amplifier for driving a second transducer with a second voltage having a second positive polarity and a second negative polarity, the system further having a capacitor having a first terminal and a second terminal, wherein the first terminal is coupled to a common terminal coupled to the first negative polarity and the second positive polarity and wherein the second terminal is coupled to a ground, the method comprising:
isolating, with a feedback path coupled to the common terminal, the first channel switching amplifier and the second channel switching amplifier from each other to ensure a flat frequency response of the system; and
controlling a voltage range of the common terminal by processing a first input signal from the first channel switching amplifier, a second input signal from the second channel switching amplifier, and a feedback signal.

20. The method of claim 19, further comprising:
receiving the first input signal, the second input signal, and the feedback signal; and
modifying the first input signal into the first channel switching amplifier and the second input signal into the second channel switching amplifier to regulate a common mode signal at the common terminal.

21. The method of claim 20, wherein the common mode signal is a common mode voltage.

22. The method of claim 19, wherein a signal being driven into the plurality of channel switching amplifiers is a differential power of the first channel switching amplifier and the second channel switching amplifier that drive the first transducer and the second transducer, respectively.

23. The method of claim 22, further comprising modifying the signal being driven into the plurality of channel switching amplifiers to regulate a common mode signal or the differential power of the first channel switching amplifier and the second channel switching amplifier.

24. The method of claim 19, wherein the plurality of channel switching amplifiers further comprise one or more additional channel switching amplifiers each having respective input signals that isolate the various channel switching amplifiers from each other and ensure a flat frequency response.

25. The method of claim 24, wherein a signal being driven into the one or more additional channel switching amplifiers is a differential power of the one or more additional channel switching amplifiers that drive the transducers.

26. The method of claim 25, further comprising closing a loop around a third or more channel switching amplifier with the feedback path of a common mode signal and a feed forward path that calculates the differential power of the plurality of channel switching amplifiers.

27. The method of claim 25, further comprising calculating, with a differential filter that receives a return control signal, the differential power of the plurality of channel switching amplifiers.

28. The method of claim 25, further comprising modifying a signal being driven into the plurality of channel switching amplifiers to regulate a common mode signal or the differential power of the plurality of channel switching amplifiers.

29. The method of claim 28, further comprising modifying the signal being driven into the plurality of channel switching amplifiers by compression to a playback signal into the plurality of channel switching amplifiers.

30. The method of claim 28, further comprising modifying the signal being driven into the plurality of channel switching amplifiers by expansion to a playback signal into the plurality of channel switching amplifiers.

31. The method of claim 28, further comprising modifying the signal being driven into the plurality of channel switching amplifiers by modifying one or more filters on a playback signal into the plurality of channel switching amplifiers.

32. The method of claim 31, further comprising modifying the one or more filters by at least one of the following: moving filter corner frequencies, altering attenuation, altering gain, and altering a quality factor of the one or more filters.

33. The method of claim 32, further comprising, a channel switching amplifier that has low frequency signals, adding one or more high frequency signals for regulating the common mode signal.

34. The method of claim 28, further comprising modifying the signal being driven into the plurality of channel switching amplifiers by adding signals into a playback signal into the plurality of channel switching amplifiers.

35. A method comprising:
receiving a first input signal from a first channel switching amplifier of a multi-channel amplifier and a second input signal from a second channel switching amplifier of the multi-channel amplifier, wherein the first channel switching amplifier and the second channel switching amplifier share a capacitor that has a first terminal coupled to a common terminal that is coupled to a first negative polarity of the first channel switching amplifier and a second positive polarity of the second channel switching amplifier and a second terminal that is coupled to a ground; and
modifying the first input signal into the first channel switching amplifier and the second input signal into the second channel switching amplifier to regulate a common mode signal at the common terminal.

36. The method of claim 35, further comprising modifying the common mode signal, wherein the common mode signal is a voltage in a voltage range or a current in a current range for the common terminal and is modified to improve an efficiency of the multi-channel amplifier.
